(19) United States
(12) Patent Application Publication
(10) Pub. No.: US 2008/0251937 A1
(43) Pub. Date: Oct. 16, 2008

(54) Stackable semiconductor device and manufacturing method thereof

(75) Inventors: Chin-Huang Chang, Taichung Hsien (TW); Chien-Ping Huang, Taichung (TW); Chih-Ming Huang, Hsinchu Hsien (TW); Cheng-Hsu Hsiao, Taichung Hsien (TW)

Correspondence Address: Edwards Angell Palmer & Dodge LLP, P.O. Box 55874, Boston, MA, 02205, US

(73) Assignee: Siliconware Precision Industries Co., Ltd., Taichung (TW)

(21) Appl. No.: 12/082,724

(22) Filed: Apr. 11, 2008

(30) Foreign Application Priority Data
Apr. 11, 2007 (TW) 096112653

(51) Int. Cl. H01L 23/52; H01L 21/00

(52) U.S. Cl. 257/777; 438/109; 257/E23.141; 257/E21.001

(57) ABSTRACT

A stackable semiconductor device and a manufacturing method thereof are disclosed. The method includes providing a wafer comprised of a plurality of chips, wherein a plurality of solder pads are formed on the active surface of each chip, and a plurality of grooves are formed between the solder pads of any two adjacent ones of the chips; forming a dielectric layer on regions between the solder pads of any two adjacent ones of the chips ; forming a metal layer on the dielectric layer electrically connected to the solder pads and forming a connective layer on the metal layer, wherein the width of the connective layer is smaller than that of the metal layer; cutting along the grooves to break off the electrical connection between adjacent chips; thinning the non-active surface of the wafer to the extent that the metal layer is exposed from the wafer; and separating the chips to form a plurality of stackable semiconductor devices. Accordingly, a multi-chip stack structure can be obtained by stacking and electrically connecting a plurality of semiconductor devices through the electrical connection between the connective layer of a semiconductor device and the metal layer of another semiconductor device, thereby effectively integrating more chips without having to increase the stacking area, and further the problems of poor electrical connection, complicated manufacturing processes and high costs known in the prior art can be avoided.

### BACKGROUND OF THE INVENTION

1. Field of the Invention

The present invention relates generally to semiconductor devices and manufacturing method thereof, and more particularly to a stackable semiconductor device with vertically stackable capability and the manufacturing method thereof.

2. Description of Related Art

Currently, multi-chip module (MCM) semiconductor packages have been developed for meeting requirement of high integration and miniaturization, through which portable and multifunctional electronic products can be manufactured and applied in the areas of such as communication, network and computers. A MCM semiconductor package generally comprises more than two chips mounted to a substrate or a lead-frame.

FIG. 1 shows a conventional multi-chip semiconductor package with horizontally spaced chips. As shown in FIG. 1, the package structure includes a substrate 100; a first chip 110 having an active surface 110a and a non-active surface 110b opposed to the active surface 110a, wherein the non-active surface 110b of the first chip 110 is adhered to the substrate 100 and the active surface 110a of the first chip 110 is electrically connected to the substrate 100 through first conductive wires 120; and a second chip 140 having an active surface 140a and a non-active surface 140b opposed to the active surface 140a, wherein the non-active surface 140b is adhered to the substrate 100 and spaced at a certain interval from the first chip 110, and the active surface 140a of the second chip 140 is electrically connected to the substrate 100 through second conductive wires 150.

One drawback of the above-described multi-chip semiconductor package is that the chips must be spaced from each other at a certain interval to prevent wire miscontact between the chips. Accordingly, a big die attachment region is needed in order to accommodate a plurality of chips, which thus increases the manufacturing cost and makes it difficult to meet demands for thinner, shorter, smaller and lighter electronic products.

FIG. 2 shows a semiconductor package disclosed by U.S. Pat. No. 6,538,331, wherein a first chip 210 and a second chip 240 are stack mounted to a substrate 200 and the second chip 240 is offset a certain interval from the first chip 210 for facilitating bonding of wires 220, 250 respectively from the first and second chips 210, 240 to the substrate 200.

Such a structure saves much more substrate spaces compared with semiconductor packages with horizontally spaced chips. However, as the chips and the substrate of the package structure are electrically connected by a plurality of bond wires, the electrical connection between the chips and the substrate can be adversely affected by length of the bond wires, thus resulting in a poor electrical connection of the structure. Meanwhile, the amount of the chips that can be accommodated by the structure is limited by spaces required by chip offset and wire bonding.

Therefore, U.S. Pat. No. 6,642,081, No. 5,270,261 and No. 6,809,421 disclose a TSV (Through Silicon Via) technique used to vertically stack a plurality of semiconductor chips and establish electrical connections therebetween. However, as the TSV technique is too complicated and needs a high cost, its practical use in the industry is limited.

Therefore, it is urgent to overcome the above drawbacks and develop a multi-chip stack structure and a manufacturing method thereof that can efficiently integrate much more chips without increasing the stacking area, and avoid poor electrical quality associated with the use of the wire bonding technique and the complicated process and high cost associated with the use of the TSV technique.

### SUMMARY OF THE INVENTION

According to the above drawbacks, an objective of the present invention is to provide a stackable semiconductor device and the manufacturing method thereof, that allow at least two stackable semiconductor devices to be vertically stacked without increasing the stacking area required for vertical stacking.

Another objective of the present invention is to provide a stackable semiconductor device and manufacturing method thereof, which prevents the use of TSV technique, thereby simplifying the process and saving the manufacturing cost.

A further objective of the present invention is to provide a stackable semiconductor device and manufacturing method thereof, which prevents the use of the wire bonding technique and accordingly prevents the problem of poor electrical connection caused by the use of bonding wires.

In order to attain the above and other objectives, the present invention discloses a manufacturing method of a stackable semiconductor device, which comprises the steps of: providing a wafer having a plurality of chips, wherein the chips and the wafer each has an active surface and a non-active surface opposed to the active surface, and a plurality of solder pads are formed on the active surface of each of the chips; forming a plurality of grooves on regions of the wafer between the solder pads of any two adjacent ones of the chips; forming a dielectric layer over the regions of the wafer, allowing the grooves to be covered by the dielectric layer; forming a metal layer on the dielectric layer and allowing the metal layer to be electrically connected to the solder pads of the chips; forming a connective layer on the metal layer; cutting the wafer along the grooves to a depth greater than that of each of the grooves so as to break off electrical connection between any two adjacent ones of the chips; thinning the wafer via the non-active surface to the extent that the metal layer formed in each of the grooves is exposed from the non-active surface of the wafer; and separating the chips to obtain a plurality of stackable semiconductor devices. The metal layer can be such as a Cu/Ni layer. The connective layer can be made of a solder material.

Thereafter, a semiconductor device thus-obtained is capable of being stacked on another can be stacked on another semiconductor device thus-obtained, allowing the metal layer exposed from the non-active surface of the chip of the semiconductor device to be in direct contact with and electrically connected to the connective layer on the active surface of the chip of the another semiconductor device, thereby allowing the two stacked semiconductor devices to form a multi-chip stack structure.

Through the above-described manufacturing method, the present invention further discloses a stackable semiconductor device, which comprises: a chip having an active surface and a non-active surface opposed to the active surface, a plurality of solder pads being formed on the active surface of the chip; a dielectric layer formed on the solder pads and on regions extending from the solder pads to edges of the active surface of the chip and further to sidewalls of the chip; a metal layer formed on the dielectric layer and exposed from the non-active surface of the chip and electrically connected to the solder pads on the active surface of the chip; and a connective layer formed on the metal layer in position corresponding to the edges of the active surface of the chip.

Therefore, according to the stackable semiconductor device and manufacturing method of the present invention, a wafer having a plurality of chips is provided, wherein both the chips and the wafer each has an active surface and an opposing non-active surface, a plurality of solder pads are formed on the active surface of each of the chips, and grooves are formed on regions of the wafer between the solder pads of any two adjacent ones of the chips; a dielectric layer is formed over the regions of the wafer, allowing the grooves to be covered by the dielectric layer; a metal layer is formed on the dielectric layer and allowing the metal layer to be electrically connected to the solder pads of the chips; a connective layer made of such as a solder material is formed on the metal layer, wherein the width of the connective layer is smaller than that of the metal layer; the wafer is cutting along the grooves to a depth greater than that of each of the grooves so as to break off electrical connection between any two adjacent ones of the chips; the wafer is thinned via the non-active surface thereof to the extent that the metal layer formed in each of the grooves is exposed from the non-active surface of the wafer; and the wafer is then singluated so as to obtain a plurality of stackable semiconductor devices. Accordingly, such a semiconductor device can be disposed on a chip carrier through its non-active surface and electrically connected with the chip carrier through the metal layer exposed from the non-active surface, and another semiconductor device can be stacked on the above-described semiconductor device with the metal layer exposed from the non-active surface of the another semiconductor device being in direct contact with and electrically connected to the connective layer of the underlied semiconductor device. Thus, a multi-chip stack structure is obtained. As the stackable semiconductor devices are capable of being vertically stacked according to the present invention, that two stackable semiconductor devices can be efficiently integrated in a multi-chip stack structure according to the present invention without increasing the stacking area required for stacking implementation, thereby improving the electrical performance of the multi-chip stack structure. Meanwhile, the present invention avoids the use of the wire bond technique and the TSV technique, thus preventing the problem of poor electrical connection resulting from the use of bonding wires and the problems of complicated process and high cost associated with the use of the TSV technique.

### BRIEF DESCRIPTION OF DRAWINGS

FIG. 1 is a sectional diagram of a conventional semiconductor package with multiple chips horizontally spaced from each other;

FIG. 2 is a sectional diagram of a semiconductor package with stacked chips disclosed by U.S. Pat. No. 6,538,33 1;

FIGS. 3A to 3I are sectional diagrams of a stackable semiconductor device and manufacturing method thereof according to a first embodiment of the present invention;

FIG. 4 is a sectional diagram showing a stacking structure of the semiconductor device according to a first embodiment of the present invention; and

FIGS. 5A to 5C are sectional diagrams showing a manufacturing method of a stackable semiconductor device according to a second embodiment of the present invention.

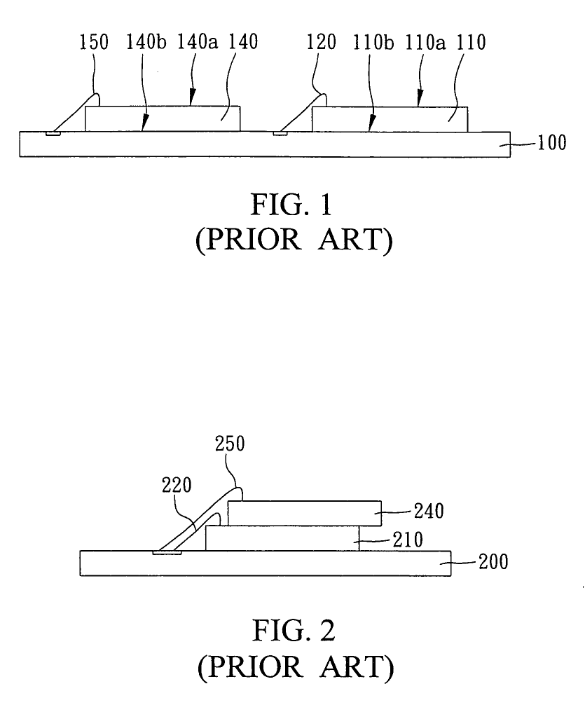

### DETAILED DESCRIPTION OF PREFERRED EMBODIMENTS

The following illustrative embodiments are provided to illustrate the disclosure of the present invention, these and other advantages and effects can be apparent to those skilled in the art after reading the disclosure of this specification. The present invention can also be performed or applied by other different embodiments. The details of the specification may be on the basis of different points and applications, and numerous modifications and variations can be made without departing from the spirit of the present invention.

### First Embodiment

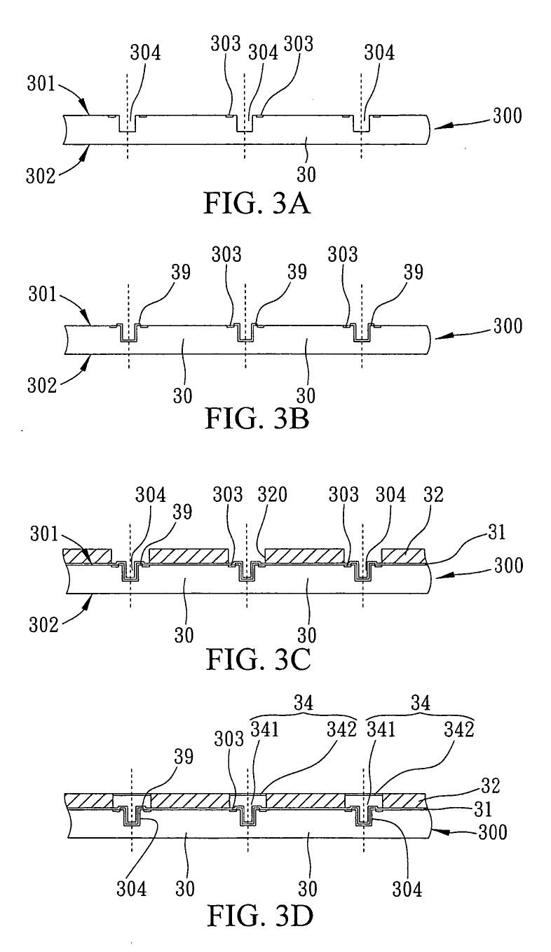

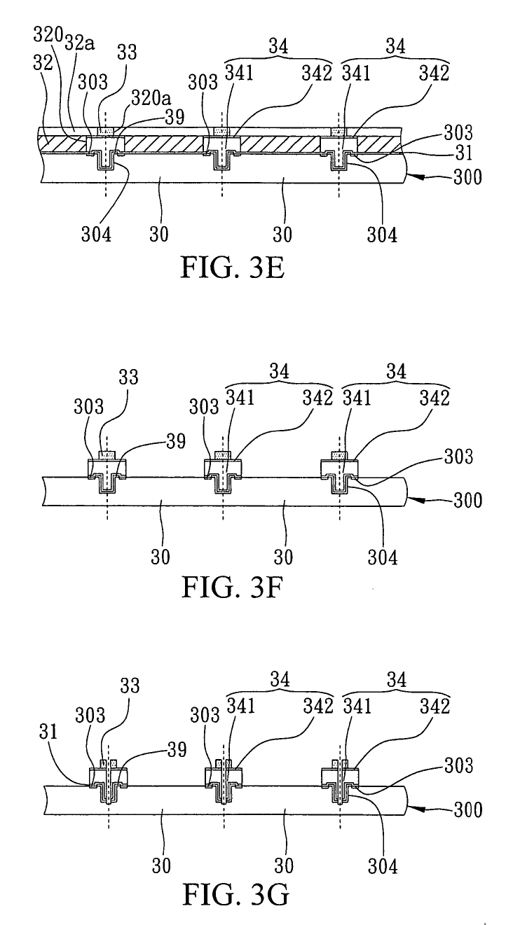

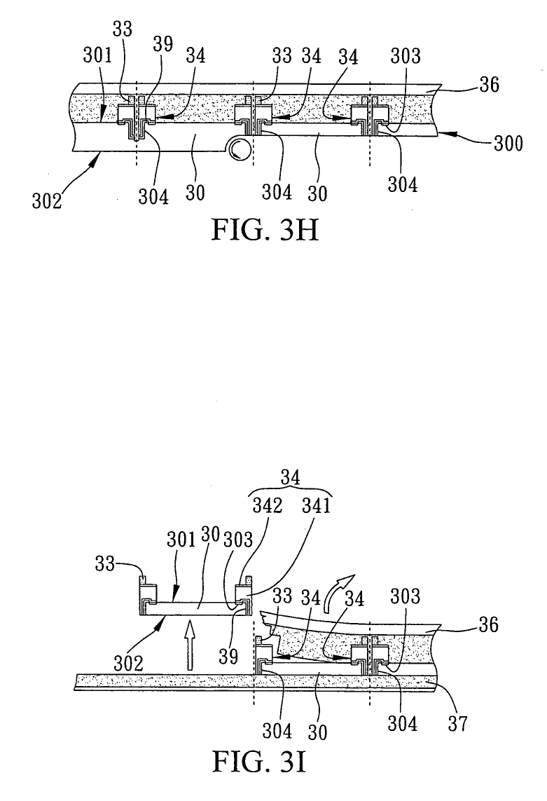

FIGS. 3A to 3I are diagrams showing a stackable semiconductor device and a manufacturing method thereof according to a first embodiment of the present invention.

As shown in FIG. 3A, a wafer 300 having a plurality of chips 30 is provided. The chips 30 and the wafer 300 have an active surface 301 and a non-active surface 302 opposed to the active surface 301. A plurality of solder pads 303 is disposed on the active surface 301 of each chip and grooves 304 are formed between the solder pads 303 of any two adjacent ones of the chips. The grooves 304 have a width of approximately 80 μm to 120 μm.

As shown in FIG. 3B, a dielectric layer 39 is formed on the active surface 301 of the wafer 300 and patterned such that the dielectric layer 39 can cover the regions between the solder pads 303 of adjacent chips, the grooves 304 formed therebetween as well as inside the grooves 304. The dielectric layer 39 may be made of such as BCB (Benzo-Cyclo-Butene) and polyimide, which is approximately 1 μm to 3 μm thick.

As shown in FIG. 3C, a conductive layer 31 made of Ti/Cu, TiW/Cu or Al/NiV/Cu is formed on the active surface 301 of the wafer 300 and the dielectric layer 39 by such as sputtering, and then covered by a first resist layer 32. A plurality of first openings 320 is formed in the first resist layer 32 so as to expose the conductive layer 31 on the solder pads 303 of adjacent chips and the dielectric layer 39.

As shown in FIG. 3D, an electroplating process is performed so as to form a metal layer 34 consisted in sequence of a copper layer 341 and a nickel layer 342 in the first openings 320 and the metal layer 34 is electrically connected with the solder pads 303. The a copper layer 341 has a thickness of approximately 10 μm to 40 μm, and the nickel layer 342 has a thickness of approximately 2 μm to 5 μm.

As shown in FIG. 3E, a second resist layer 32a is formed on the first resist layer 32 and a plurality of second openings 320a is formed in the second resist layer 32a corresponding in position to the grooves 304 and having a diameter smaller than that of the first openings 320 so as to partially expose the metal layer 34.

Then, a connective layer 33 of a metal material is formed on the metal layer 34 in the second openings 320a by electroplating. The connective layer 33 has a thickness of approximately 10 μm to 30 μm, which may be made of a solder material containing lead or a lead-free solder material such as Sn—Ag alloy, Sn—Cu alloy and the like.

As shown in FIG. 3F, the first and second resist layers 32, 32a and the conductive layer 31 covered by the first and second resist layers 32, 32a are removed.

As shown in FIG. 3G, the wafer 300 is cut at positions of the grooves 304 between the chips 30 to a depth greater than the grooves 304, thereby breaking off the electrical connection between adjacent chips 30. That is, the connective layers 33, the metal layers 34 and the conductive layers 31 of adjacent chips 30 are respectively separated from each other.

As shown in FIG. 3H, the wafer 300 is adhered to a carrier board 36 through its active surface 301 by such as a UV tape, and the non-active surface 302 of the wafer 300 is thinned to a position where the grooves 304 are located such that the metal layer 34 can be exposed from the non-active surface 302 of the wafer 300.

As shown in FIG. 3I, the chips 30 are then adhered to another UV tape 37 through non-active surface thereof and the carrier board 36 is removed. Thereafter, a chip mounting process or a chip stacking process can further be performed.

Through the above-described manufacturing method, a stackable semiconductor device is disclosed, which comprises: a chip 30 having an active surface 301 and a non-active surface 302 opposed to the active surface 301, a plurality of solder pads 303 being formed on the active surface 301 of the chip 30; a dielectric layer 39 disposed at a region from the solder pads 303 to edges of the active surface 301 of the chip 30 as well as side edges of the chip 30; a metal layer 34 comprising a copper layer 341 and a nickel layer 342 disposed on the dielectric layer 39 and exposed from the non-active surface 302 of the chip 30 and electrically connected to the solder pads 303 of the active surface 301 of the chip 30; and a connective layer 33 made of such as a solder material disposed on the metal layer 34 at edges of the active surface 301 of the chip 30.

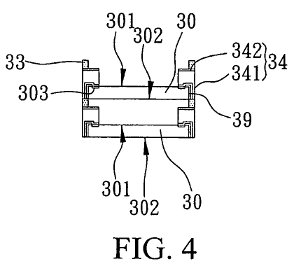

Further referring to FIG. 4, at least two above-described semiconductor devices are vertically stacked. The connective layer 33 on the metal layer 34 of the active surface 301 of the chip 30 of a first semiconductor device can form a solder joint with the metal layer 34 (Cu/Ni) on the non-active surface 302 of a second semiconductor device through a thermal compression process, thereby forming a multi-chip stack structure. Further, the connective layer 33 on the metal layer 34 of the active surface 301 of the chip 30 of a first semiconductor device can be electrically connected with the metal layer 34 on the non-active surface 302 of a second semiconductor device through a reflow process so as to form a multi-chip stack structure. In addition, a flip chip underfill material (not shown) can be filled between the stacking chips so as to fill spacing between the chips, or a no-flow underfill material can be predisposed between the chips for filling spacing between the chips.

### Second Embodiment

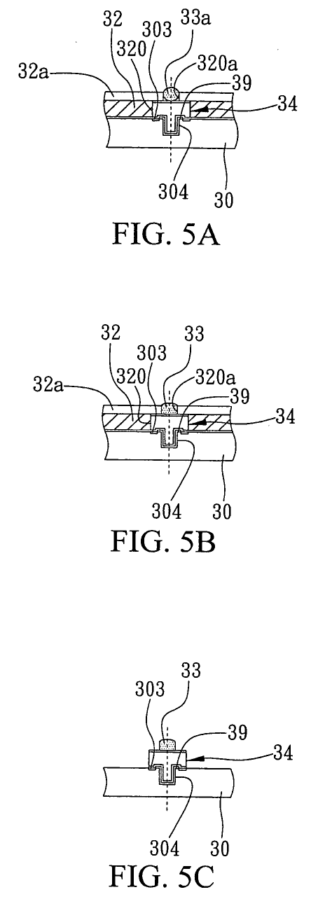

Referring to FIGS. 5A to 5C, a manufacturing method of a stackable semiconductor device according to a second embodiment of the present invention is disclosed. The manufacturing method of the present embodiment is similar to the above-described embodiment. The main difference from the above-described embodiment is the method of forming the connective layer.

As shown in FIG. 5A, similar to the method of the first embodiment, a metal layer 34 is formed on the active surface and side edges of the chip by electroplating, and a second resist layer 32a is formed on the first resist layer 32 and the metal layer 34. A second opening 320a is formed in the second resist layer 32a to partially expose the metal layer 34. The second opening 320a correspond in position to the groove 304 and smaller in diameter than the first opening 320. Subsequently, solder ball 33a is formed on the metal layer 34 in the second opening 320a.

As shown in FIG. 5B, a reflow process is performed so as to solder the solder ball 33a to the metal layer 34, thereby forming a connective layer 33.

As shown in FIG. 5C, the first and second resist layers 32, 32a and the conductive layer covered by the first and second resist layers 32, 32a are removed for exposing the metal layer 34 and the connective layer 33. Then, subsequent processes as described in the first embodiment are performed, detailed description of which is omitted.

Therefore, according to the stackable semiconductor device and manufacturing method of the present invention, a wafer having a plurality of chips is provided, wherein both the chips and the wafer each has an active surface and an opposing non-active surface, a plurality of solder pads are formed on the active surface of each of the chips, and grooves are formed between the solder pads of adjacent chips; a dielectric layer is formed to cover regions between the solder pads and the grooves and in the grooves; a metal layer is formed on the dielectric layer and electrically connected to the solder pads and a connective layer made of such as a solder material is formed on the metal layer, wherein the width of the connective layer is smaller than that of the metal layer; the non-active surface of the wafer is thinned to reach the grooves such that the metal layer can be exposed from the non-active surface of the wafer; the wafer is then singluated so as to obtain a plurality of stackable semiconductor devices. Accordingly, such a semiconductor device can be mounted on a chip carrier through its non-active surface and electrically connected with the chip carrier through the metal layer exposed from the non-active surface, and another semiconductor device can be stacked on the above-described semiconductor device with the metal layer exposed from the non-active surface of the another semiconductor device being in direct contact with and electrically connected to the connective layer of the underlied semiconductor device. Thus, a multi-chip stack structure is obtained. As the stackable semiconductor devices are capable of being vertically stacked according to the present invention, that two stackable semiconductor devices can be efficiently integrated in a multi-chip stack structure according to the present invention without increasing the stacking area required for stacking implementation, thereby improving the electrical performance of the multi-chip stack structure. Meanwhile, the present invention avoids the use of the wire bond technique and the TSV technique, thus preventing the problem of poor electrical connection resulting from the use of bonding wires and the problems of complicated process and high cost associated with the use of the TSV technique.

The above-described descriptions of the detailed embodiments are only to illustrate the preferred implementation according to the present invention, and it is not to limit the scope of the present invention, Accordingly, all modifications and variations completed by those with ordinary skill in the art should fall within the scope of present invention defined by the appended claims.

What is claimed is:

1. A manufacturing method of a stackable semiconductor device, comprising the steps of:
providing a wafer having a plurality of chips, wherein the chips and the wafer each has an active surface and a non-active surface opposed to the active surface, and a plurality of solder pads are formed on the active surface of each of the chips;
forming a plurality of grooves on regions of the wafer between the solder pads of any two adjacent ones of the chips;
forming a dielectric layer over the regions of the wafer, allowing the grooves to be covered by the dielectric layer;
forming a metal layer on the dielectric layer and allowing the metal layer to be electrically connected to the solder pads of the chips;
forming a connective layer on the metal layer;
cutting the wafer along the grooves to a depth greater than that of each of the grooves so as to break off electrical connection between any two adjacent ones of the chips;
thinning the wafer via the non-active surface thereof to the extent that the metal layer formed in each of the grooves is exposed from the non-active surface of the wafer; and
separating the chips to obtain a plurality of stackable semiconductor devices.

2. The manufacturing method of claim 1, wherein the dielectric layer is first formed on the active surface of the wafer and then patterned, allowing the dielectric layer, after being patterned, to merely cover the regions and grooves of the wafer, and the dielectric layer is made of BCB (Benzo-Cyclo-Butene) or polyimide.

3. The manufacturing method of claim 1, wherein forming the metal layer on the dielectric layer comprises the steps of:
forming a conductive layer on the active surface of the wafer and the dielectric layer;
forming a first resist layer on the conductive layer, followed by forming a plurality of first openings in the first resist layer to expose the opposing solder pads of any two adjacent ones of the chips and the conductive layer on the dielectric layer; and
performing an electroplating process to form the metal layer in the first openings of the first resist layer so as to electrically connect the metal layer to the solder pads of the chips.

4. The manufacturing method of claim 3, wherein the conductive layer is made of a material selected from the group consisting of Ti/Cu, TiW/Cu and Al/NiV/Cu.

5. The manufacturing method of claim 3, wherein the metal layer comprises a copper layer and a nickel layer.

6. The manufacturing method of claim 3, wherein the step of forming a connective layer on the metal layer comprises the steps of:
forming a second resist layer on the first resist layer, followed by forming a plurality of second openings in the second resist layer corresponding in position to the grooves, wherein the second openings are smaller in diameter than the first openings, and the metal layer is partially exposed through the second openings;
forming a connective layer made of a metal material on the metal layer in the second openings by electroplating; and
removing the first and second resist layers and the conductive layer covered by the first and second resist layers.

7. The manufacturing method of claim 6, wherein the connective layer is made of one of a solder material containing lead and a lead-free solder material.

8. The manufacturing method of claim 3, wherein the step of forming a connective layer on the metal layer comprises the steps of:
forming a second resist layer on the first resist layer, followed by forming a plurality of second openings in the second resist layer corresponding in position to the grooves, wherein the second openings are smaller in diameter than the first openings, and the metal layer is partially exposed through the second openings;
mounting solder balls on the metal layer via the second openings;
reflowing the solder balls to form a connective layer on the metal layer exposed from each of the second openings; and
removing the first and second resist layers and the conductive layer covered by the first and second resist layers.

9. The manufacturing method of claim 1, wherein, prior to the thinning of the non-active surface of the wafer, a carrier board is adhered to the active surface of the wafer, such that the non-active surface of the wafer can be thinned to reach the grooves.

10. The manufacturing method of claim 1, wherein the semiconductor device thus-obtained is capable of being stacked on another semiconductor device thus-obtained, allowing the metal layer exposed from the non-active surface of the chip of the semiconductor device to be in direct contact with and electrically connected to the connective layer on the active surface of the chip of the another semiconductor device, thereby forming a multi-chip stack structure.

11. The manufacturing method of claim 10, wherein the connective layer is made of a solder material, such that, by a thermal compression process or a reflow process, the connective layer is formed into a plurality of solder joints between the stacked semiconductor devices for allowing the stacked semiconductor devices to be electrically connected via the solder joints.

12. The manufacturing method of claim 10, wherein a filling material is filled in a spacing between the stacked semiconductor devices that form the multi-chip stack structure.

13. A stackable semiconductor device, comprising:
a chip having an active surface and a non-active surface opposed to the active surface, a plurality of solder pads being formed on the active surface of the chip;
a dielectric layer formed on the solder pads and on regions extending from the solder pads to edges of the active surface of the chip and further to sidewalls of the chip;
a metal layer formed on the dielectric layer and exposed from the non-active surface of the chip and electrically connected to the solder pads on the active surface of the chip; and
a connective layer formed on the metal layer in position corresponding to the edges of the active surface of the chip.

14. The stackable semiconductor device of claim 13 further comprising a conductive layer formed between the metal layer and the chip.

15. The stackable semiconductor device of claim 14, wherein the conductive layer is made of a material selected from the group consisting of Ti/Cu, TiW/Cu and Al/NiV/Cu.

16. The stackable semiconductor device of claim 13, wherein the metal layer comprises a copper layer and a nickel layer.

17. The stackable semiconductor device of claim 13, wherein the connective layer is made of one of a solder material containing lead and a lead-free solder material.

18. The stackable semiconductor device of claim 13, wherein the metal layer exposed from the non-active surface of the semiconductor device is capable of being in direct contact with and electrically connected to the connective layer on the active surface of another semiconductor device on which the semiconductor device is stacked, thereby allowing the two stacked semiconductor devices to form a multi-chip stack structure.

19. The stackable semiconductor device of claim 18, wherein the connective layer is made of a solder material, such that, through a reflow process or a thermal compression process, the connective layer is allowed to form with a plurality of solder joints between the stacked semiconductor devices for allowing the stacked semiconductor devices can be electrically connected through the solderjoints.

20. The stackable semiconductor device of claim 18, wherein a filling material is filled between a spacing between the stacked semiconductor devices that form the multi-chip stack structure.
